(19) United States
(12) Patent Application Publication
(10) Pub. No.: US 2025/0324609 A1
(43) Pub. Date: Oct. 16, 2025

(54) EPITAXIAL REGROWTH IN ACTIVE AREA OF SEMICONDUCTOR DEVICE

(71) Applicant: Micron Technology, Inc., Boise, ID (US)

(72) Inventors: Jordan D. GREENLEE, Boise, ID (US); Protyush SAHU, Boise, ID (US); Silvia BORSARI, Boise, ID (US); Pavan Reddy K AELLA, Eagle, ID (US); Hunter H. LEAKE, Boise, ID (US); Che-Chi LEE, Boise, ID (US); Thomas A. FIGURA, Boise, ID (US); James DAHL, Boise, ID (US)

(21) Appl. No.: 19/174,438

(22) Filed: Apr. 9, 2025

Related U.S. Application Data
(60) Provisional application No. 63/632,912, filed on Apr. 11, 2024.

(51) Int. Cl. H10B 53/30

(52) U.S. Cl. CPC H10B 53/30

(57) ABSTRACT

Implementations described herein relate to various structures, integrated assemblies, and memory devices. In some implementations, an integrated assembly includes an elemental region having a first width. The elemental region includes a first native portion of a semiconductive material. The integrated assembly further includes a composite region over the elemental region and having a second width that is greater than or equal to the first width. The composite region includes a second native portion of the semiconductive material that is directly conjoined with the first native portion, and a reconstituted portion of the semiconductive material that is directly conjoined with the second native portion and that extends away from the second native portion.

### CROSS-REFERENCE TO RELATED APPLICATION

This patent application claims priority to U.S. Provisional Patent Application No. 63/632,912, filed on Apr. 11, 2024, entitled “EPITAXIAL REGROWTH IN ACTIVE AREA OF SEMICONDUCTOR DEVICE,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to epitaxial regrowth in an active area of a semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell.

FIG. 2 is a diagrammatic view showing views of a portion of a memory device structure described herein.

FIG. 3 is a flowchart of an example method of forming an integrated assembly or memory device having epitaxial regrowth as part of an active area described herein.

FIGS. 4A through 4E are diagrammatic views showing formation of an active area at example process stages of an example process of forming the active area.

FIG. 5 is a diagrammatic view of an example memory device.

### DETAILED DESCRIPTION

A semiconductor device, such as a DRAM memory device, often includes at least one area (e.g., region) of an epitaxially grown semiconductive material used to form integrated circuitry. The area may be referred to as an active area of the semiconductor device and include a structure such as a contact structure (e.g., an active structure). In some implementations, the contact structure may be a bit contact structure that is part of an electrical connection between a transistor and a digit line of the semiconductor device. Additionally, or alternatively and in some implementations, the contact structure may be a cell contact structure that is part of an electrical connection between the transistor and a capacitor of the semiconductor device.

The active area may have at least one critical dimension (e.g., a size, width, or depth) that is essential to maintaining a performance margin of the semiconductor device. Maintaining the performance margin may enable the semiconductor device to account for variability in manufacturing processes, improve a quality and/or a reliability of the semiconductor device, and satisfy performance requirements of the semiconductor device under various environments, operating conditions, and/or applications.

In some cases, techniques to form the active area include forming a dielectric layer over and/or around the active area and forming a recess in the dielectric layer adjacent to the active area. Forming the recess may inadvertently consume a portion of the active area such that the critical dimension fails to satisfy a lower threshold, thereby reducing an ability of the semiconductor device to maintain the performance margin.

Some implementations described herein include a semiconductor device including an active area and methods of formation. The active area includes an elemental region and a composite region, where each region includes a semiconductive material. Within the elemental region, the semiconductive material may be wholly formed using a single growth operation. In contrast, and within the composite region, at least a portion of the semiconductive material is reconstituted (e.g., epitaxially regrown, redeposited) to recover semiconductive material that is lost through manufacturing and to maintain (or increase) a width of the active area to satisfy a threshold.

In this way, a width of the active area is preserved, to maintain and/or increase a performance margin of the semiconductor device, to account for variability in manufacturing processes, improve a quality and/or reliability of the semiconductor device, and satisfy performance requirements of the semiconductor device under various environments, operating conditions, and/or applications. As a result, an amount of resources used to support multiple markets consuming the memory device (e.g., labor, semiconductor manufacturing tools, raw materials, and/or computing resources) is reduced.

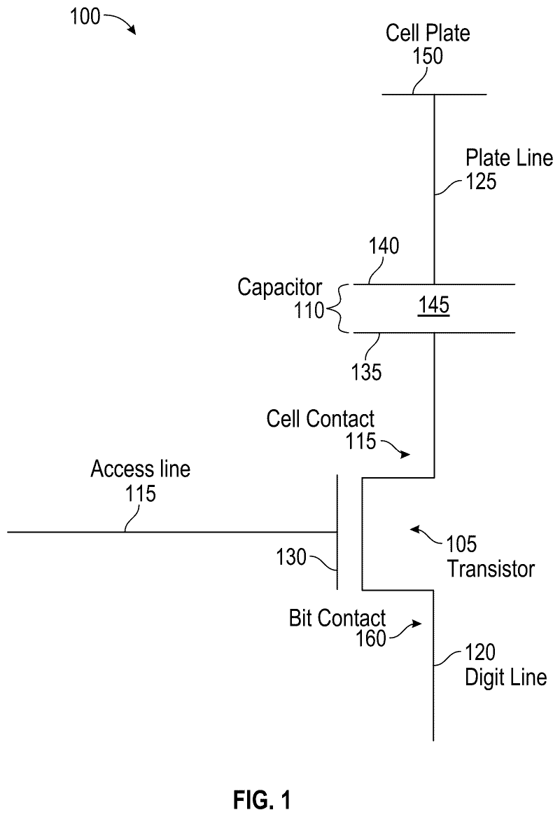

FIG. 1 is a circuit diagram of an example memory cell 100. The memory cell 100 may be included in a semiconductor device (e.g., a DRAM memory device). In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

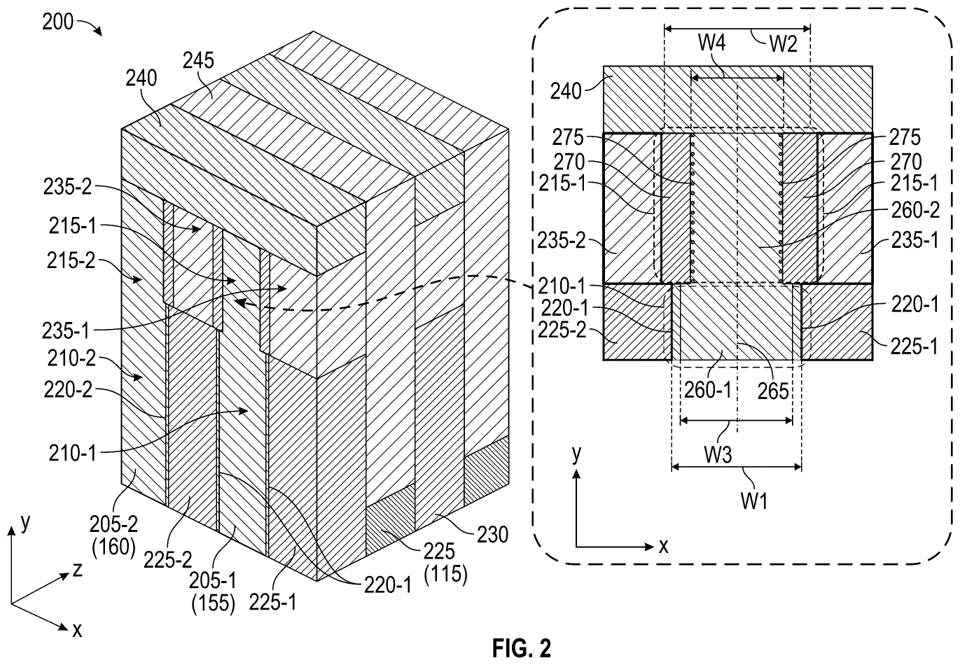

In some implementations, the memory cell 100 is accessed using a cell contact 155 and a bit contact 160. The cell contact 155 may be part of a connection between the capacitor 110 and the transistor 105, and the bit contact 160 may be part of a connection between the digit line 120 and the transistor 105. As described in greater detail in connection with FIGS. 2-5, the cell contact 155 and/or the bit contact 160 may be included in respective active areas of a semiconductor device. The active areas may include regions of epitaxial regrowth (e.g., reconstituted portions of a semiconductive material) to maintain a performance margin of the memory cell 100.

As indicated above, FIG. 1 is provided as an example. Other examples may differ from what is described with respect to FIG. 1.

FIG. 2 is a diagrammatic view showing views of a portion of a memory device structure 200 described herein. The memory device structure 200 may include one or more features of the memory cell 100 of FIG. 1.

As shown in FIG. 2, the memory device structure 200 includes one or more elongated active areas 205 (e.g., the elongated active areas 205-1 and 205-2). Each of the elongated active areas 205 may comprise, consist of, or consist essentially of semiconductive material. The semiconductive material may comprise, consist of, or consist essentially of silicon (e.g., polycrystalline silicon). Alternatively, and in some implementations, the elongated active areas 205 may comprise, consist of, or consist essentially of silicon carbide, gallium nitride, or a type III-V element, or another suitable semiconductive material, among other examples.

Each of the elongated active areas 205 may correspond to one or more features of a memory cell (e.g., the memory cell 100 of FIG. 1). For example, the elongated active area 205-1 may correspond to a cell contact structure (e.g., the cell contact 155 of FIG. 1) and the elongated active area 205-2 may correspond to a bit contact structure (e.g., the bit contact 160 of FIG. 1).

Each of the elongated active areas 205 may include an elemental region 210 (e.g., a lower segment as viewed in FIG. 2) and a composite region 215 (e.g., an upper segment as viewed in FIG. 2). In some implementations, the elemental region 210 includes an oxidized sidewall 220 and the composite region 215 does not include an oxidized sidewall. For example, as shown in the isometric view of FIG. 2, the elemental region 210-1 includes the oxidized sidewall 220-1 that extends from a base of the elemental region 210-1 to a base of the composite region 215-1 (e.g., the oxidized sidewall 220-1 does not penetrate into the composite region 215-1). In contrast, the composite region 215-1 does not include oxidized sidewalls.

As shown in FIG. 2, the memory device structure 200 includes one or more conductive structures 225. Each of the conductive structures 225 may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductive material (e.g., conductively-doped silicon, conductively-doped germanium, and/or conductively-doped gallium arsenide), or another suitable conductive material, among other examples. Furthermore, each of the conductive structures 225 may form a word line of the memory device structure 200 (e.g., the access line 115 of FIG. 1).

As further shown in FIG. 2, the memory device structure 200 includes one or more dielectric structures 230, 235, 240, and 245. Each of the dielectric structures 230, 235, 240, and/or 245 (e.g., dielectric layers) may be an electrical insulator and may comprise, consist of, or consist essentially of insulative material. As used herein, an insulative material may comprise, consist of, or consist essentially of an oxide (e.g., silicon oxide or aluminum oxide) and/or a nitride (e.g., silicon nitride or aluminum nitride), or another suitable insulative material, among other examples. In some implementations, one or more of the dielectric structures 230, 235, 240, and/or 245 may serve to electrically isolate the elongated active areas 205, electrically isolate the conductive structures 225, and/or perform as a hard mask structure during formation of the memory device structure 200.

Each of the elemental regions 210 and the composite regions 215 may include respective, native portions 260 of a semiconductive material (e.g., portions of a semiconductive material formed using an initial, or first, epitaxial growth operation). For example, and as shown in the detailed cross section view of FIG. 2, the elemental region 210-1 includes a native portion 260-1 (e.g., a first native portion) of a semiconductive material and the composite region 215-1 includes a native portion 260-2 (e.g., a second native portion) of the semiconductive material, where the native portion 260-2 is over and/or on (e.g., directly conjoined with) the native portion 260-1. The native portions 260-1 and 260-2 may be disposed along an axis 265 (e.g., a vertical axis as viewed in FIG. 2).

Each of the composite regions 215 may further include a reconstituted portion 270 of a semiconductive material (e.g., portions of a semiconductive material formed using a second epitaxial growth operation). For example, and as shown in the detailed cross section view of FIG. 2, the composite region 215-1 includes the reconstituted portion 270.

In some implementations, the reconstituted portion 270 is over and/or on (e.g., directly conjoined with) a native semiconductive material along one or more interface region 275. For example, and as shown in the detailed cross section view of FIG. 2, the reconstituted portion 270 is over and/or on the native portion 260-2 along the interface region 275, and the reconstituted portion 270 is over and/or on the native portion 260-2 along the interface region 275. The reconstituted portion 270 may extend away from the axis 265 (e.g., extend laterally away as viewed in FIG. 2).

Features of the elemental regions 210 and/or the composite regions 215 may have one or more interrelated dimensions. For example, and as shown in the detailed cross section view of FIG. 2, a width W1 of the elemental region 210-1 may be less than or equal to a width W2 of the composite region 215-1. Additionally, or alternatively, a width W3 of the native portion 260-1 may be greater than or equal to a width W4 of the native portion 260-2.

In some implementations, a ratio of the width W2 to the width W1 (W2:W1) is included in a range of approximately 21:20 to approximately 32:20 (e.g., approximately 1.05× to approximately 1.6×). If the ratio W2:W1 is less than approximately 21:20, an ability of the elongated active areas 205 to satisfy a performance margin threshold within the memory device structure 200 may be reduced. If the ratio W2:W1 is between approximately 21:20 and 32:20, the ability of the elongated active areas 205 to satisfy the performance margin threshold may be maintained and/or increased and the elongated active areas 205 may maintain electrical isolation within the memory device structure 200. If the ratio W2:W1 is greater than approximately 32:20, bridging may occur among the active areas 205 to cause electrical shorting within the memory device structure 200. However, other values and ranges for the ratio W2:W1 are within the scope of the present disclosure.

Features of the elemental regions 210 and/or the composite regions 215 may further have one or more spatial relationships that are interrelated and/or one or more spatial relationships with features of the memory device structure 200. For example, and as further shown in the detailed cross section view of FIG. 2, the reconstituted portion 270 may overlap the oxidized sidewall 220. Additionally, or alternatively, the dielectric structure 235-1 may be directly on and along a sidewall of the reconstituted portion 270. Additionally, or alternatively, the dielectric structure 235-2 may be directly on and along a sidewall of the reconstituted portion 270. Additionally, or alternatively, the dielectric structure 240 may be over and/or directly on the composite region 215-1. Additionally, or alternatively, the dielectric structure 240 may be over and/or on surfaces of the native portion 260-1 and/or the reconstituted portion 270.

In some implementations, the native portions 260 and the reconstituted portion 270 may include a same semiconductive material (e.g., the native portions 260 and the reconstituted portion 270 may each include silicon). Alternatively, and in some implementations, the native portions and the reconstituted portions may include different semiconductive materials (e.g., the native portions 260 may include silicon, and the reconstituted portion 270 may include silicon-germanium).

As indicated above, FIG. 2 is provided as an example. Other examples may differ from what is described with regard to FIG. 2.

As described in connection with FIG. 1 and FIG. 2, and in some implementations, an integrated assembly (e.g., the memory device structure 200) includes an elemental region (e.g., the elemental region 210-1) having a first width (e.g., the width W1). The elemental region includes a first native portion (e.g., the native portion 260-1) of a semiconductive material. The integrated assembly further includes a composite region (e.g., the composite region 215-1) over the elemental region and having a second width (e.g., the width W2) that is greater than or equal to the first width. The composite region includes a second native portion (e.g., the native portion 260-2) of the semiconductive material that is directly conjoined with the first native portion, and a reconstituted portion (e.g., the reconstituted portion 270) of the semiconductive material that is directly conjoined with the second native portion and that extends away from the second native portion.

Additionally, or alternatively and in some implementations, an apparatus (e.g., a memory device) includes a semiconductor structure (e.g., the memory device structure 200). The semiconductor structure includes an active area (e.g., the elongated active area 205-1) disposed along a vertical axis (e.g., the axis 265). The active area includes a lower segment (e.g., the elemental region 210-1) that includes a first portion (e.g., the portion 260-1) of a first semiconductive material, wherein the first portion has first width (e.g., the width W3). The active area further includes an upper segment (e.g., the composite region 215-1). The upper segment includes a second portion (e.g., the portion 260-2) of the first semiconductive material that is on the first portion, wherein the second portion has a second width (e.g., the width W4) that is less than or equal to the first width. The upper segment includes a regrowth portion (e.g., the reconstituted portion 270) of a second semiconductive material that is conjoined with the second portion of the first semiconductive material along an interface region (e.g., the interface region 275), wherein the regrowth portion extends laterally away from the vertical axis, and wherein the interface region includes traces of impurities.

In these ways, a width of the active area of a semiconductor device may be preserved in order to maintain and/or increase a performance margin of the semiconductor device to account for variability in manufacturing processes, improve a quality and/or reliability of the semiconductor device, and satisfy performance requirements of the semiconductor device under various environments, operating conditions, and/or applications. As a result, an amount of resources used to support multiple markets consuming the memory device (e.g., labor, semiconductor manufacturing tools, raw materials, and/or computing resources) is reduced.

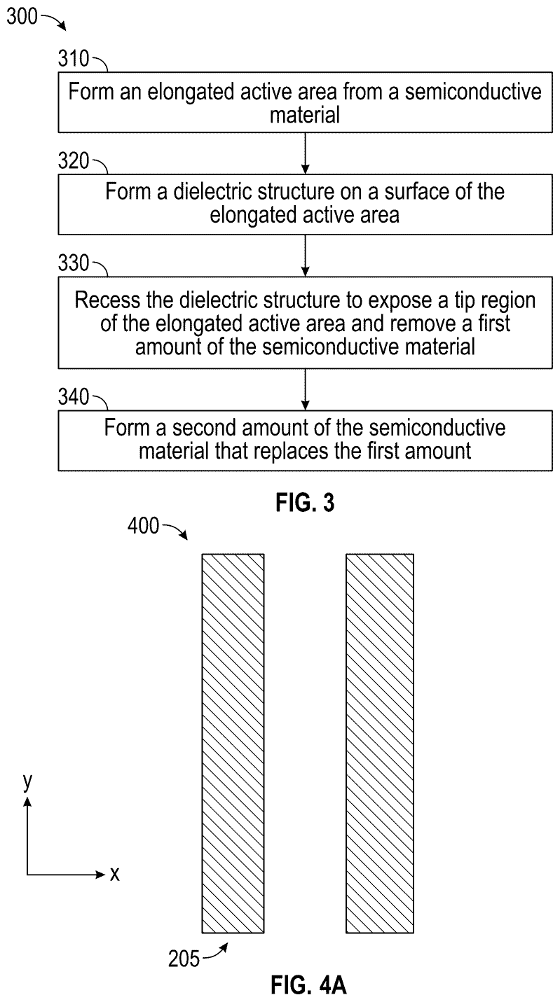

FIG. 3 is a flowchart of an example method 300 of forming an integrated assembly or memory device having epitaxial regrowth (e.g., the reconstituted portion 270) part of an active area (e.g., the elongated active areas 205) described herein. In some implementations, one or more process blocks of FIG. 3 may be performed by various semiconductor manufacturing equipment.

As shown in FIG. 3, the method 300 may include forming an elongated active area (e.g., the elongated active areas 205) from a semiconductive material (block 310). As further shown in FIG. 3, the method 300 may include forming a dielectric structure (e.g., the dielectric structures 230) on a surface of the elongated active area (block 320). As further shown in FIG. 3, the method 300 may include recessing the dielectric structure to expose a tip region of the elongated active area and remove a first amount of the semiconductive material (block 330). As further shown in FIG. 3, the method 300 may include forming a second amount of the semiconductive material (e.g., the reconstituted portion 270) that replaces the first amount (block 340).

The method 300 may include additional aspects, such as any single aspect or any combination of aspects described below and/or in connection with one or more other methods described elsewhere herein.

In a first aspect, the second amount is greater than the first amount.

In a second aspect, alone or in combination with the first aspect, forming the second amount includes forming the second amount using an epitaxial regrowth operation.

In a third aspect, alone or in combination with one or more of the first and second aspects, forming the second amount using the epitaxial regrowth operation includes selectively forming the second amount directly on an exposed surface of the elongated active area in the tip region.

In a fourth aspect, alone or in combination with one or more of the first through third aspects, forming the second amount includes forming an interface region (e.g., the interface region 275).

In a fifth aspect, alone or in combination with one or more of the first through fourth aspects, forming the interface region includes forming traces of chlorine in the interface region, forming traces of fluorine in the interface region, or forming traces of nitrogen in the interface region.

In a sixth aspect, alone or in combination with one or more of the first through fifth aspects, the method 300 includes forming a dielectric structure (e.g., the dielectric structures 235) along a sidewall of the second amount.

In a seventh aspect, alone or in combination with one or more of the first through sixth aspects, the dielectric structure is a first dielectric structure, and the method 300 includes forming a second dielectric structure (e.g., the dielectric structures 240) directly on an exposed surface of the first dielectric structure and an exposed surface of the elongated active area that includes an exposed surface of the second amount.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming one or more active areas (e.g., the elongated active areas 205), and integrated assembly that includes the active areas, any part described herein of the active areas, and/or any part described herein of an integrated assembly that includes the active areas. For example, the method 300 may include forming a structure of a semiconductor device (e.g., the memory device structure 200), an original portion of a semiconductive material in the active areas (e.g., the native portion 260-1 and/or the native portion 260-2), and or a regrowth portion of a semiconductive material in the active area (e.g., the reconstituted portion 270).

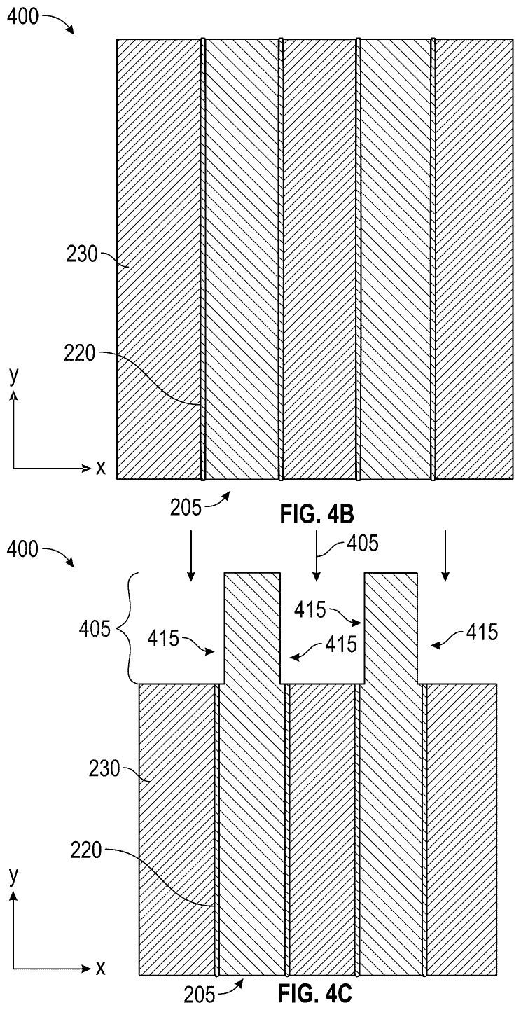

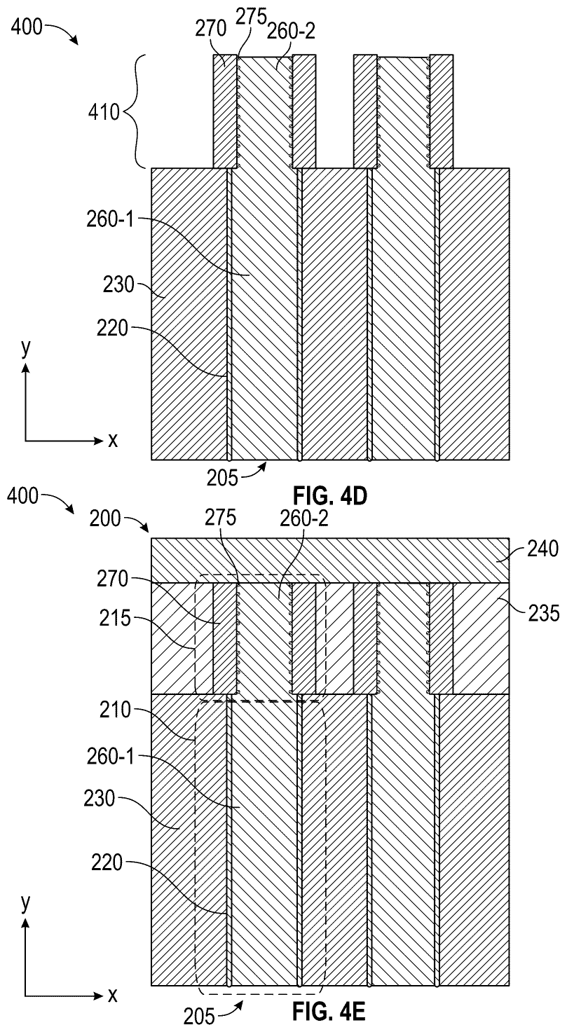

FIGS. 4A through 4E are diagrammatic views showing formation of an active area (e.g., the elongated active areas 205) at example process stages of an example process of forming the active area. In some implementations, the example process described below in connection with FIGS. 4A through 4E may correspond to the method 300 and/or one or more blocks of the method 300. However, the process described below is an example, and other example processes may be used to form the active area, an integrated assembly (e.g., a semiconductor device such as a memory device) that includes the active area, and/or one or more parts of the active area and/or the integrated assembly.

As shown in FIG. 4A, the process 400 may include forming one or more elongated active areas 205. Forming the elongated active areas 205 may include depositing (e.g., depositing or epitaxially growing) a semiconductive material. The semiconductive material used to form the elongated active areas 205 may comprise, consist of, or consist essentially of silicon (e.g., polycrystalline silicon). Alternatively, the semiconductive material used to form the elongated active areas may comprise silicon carbide, gallium nitride, a type III-V element, or another suitable semiconductive material among other examples.

As further shown in FIG. 4A, the process 400 may include removing (e.g., etching) a portion of the semiconductive material. In some implementations, one or more masks may be used to form the elongated active areas 205. For example, one or more masks (e.g., photoresist masks) may be deposited and/or patterned on the semiconductive material prior to removing portions of the semiconductive material to form the elongated active areas 205.

As shown in FIG. 4B, the process 400 may include forming the dielectric structures 230 (e.g., one or more dielectric layers) on surfaces of the elongated active areas 205. Forming the dielectric structures 230 may include depositing (e.g., depositing or growing) an insulative material. The insulative material used to form the dielectric structures 230 may comprise, consist of, or consist essentially of oxide (e.g., silicon dioxide or aluminum oxide). Alternatively, the insulative material used to form the dielectric structures 230 may comprise, consist, or consist essentially of nitride (e.g., silicon nitride or aluminum nitride) or another suitable insulative material, among other examples. In some implementations, forming the dielectric structures may include oxidizing surfaces of the elongated active areas 205 to form the oxidized sidewall 220.

As shown in FIG. 4C, the process 400 may include recessing the dielectric structures 230 (e.g., forming recesses 405 in the dielectric structures 230) to expose tip regions 410 of the elongated active areas 205. In some implementations, one or more masks may be used. For example, one or more masks (e.g., photoresist masks) may be deposited and/or patterned on the elongated active areas 205 prior to removing material to form recesses 405.

In some implementations, and as further shown in FIG. 4C, recessing the dielectric structures 230 may remove portions of the oxidized sidewall 220 and/or amounts 415 of the semiconductive material from elongated active areas 205 in the tip regions 410. In other words, recessing the dielectric structures 230 may thin the elongated active areas 205 and/or the semiconductive material in the tip regions 410.

As shown in FIG. 4D, the process 400 may include forming the reconstituted portion 270. Forming the reconstituted portion 270 may include replacing an amount (e.g., a first amount) of the semiconductive material removed from the elongated active areas 205 during recessing of the dielectric structures 230 as described in connection with FIG. 4C (e.g., the amounts 415 removed from the tip regions 410). In some implementations, a replacement amount (e.g., a second amount) of the reconstituted portion 270 is greater than or equal to the amount of the semiconductive material removed. In some implementations, the reconstituted portion 270 is selectively formed (e.g., epitaxially grown) on exposed surfaces of the elongated active areas 205, and not formed on other surfaces (e.g., on surfaces of the dielectric structures 230).

In some implementations, forming the reconstituted portion 270 includes depositing (e.g., epitaxially growing) a same semiconductive material as used to form the elongated active areas 205 as described in connection with FIG. 4A. Alternatively, and in some implementations, forming the reconstituted portion 270 includes depositing (e.g., epitaxially growing) a different semiconductive material than the semiconductive material used to form the elongated active areas 205 as described in FIG. 4A. The semiconductive material used to form the reconstituted portion 270 may comprise, consist of, or consist essentially of silicon (e.g., polycrystalline silicon). Alternatively, the semiconductive material used to form the reconstituted portion 270 may comprise, consist of, or consist essentially of silicon carbide, gallium nitride, a type III-V element, or another suitable semiconductive material, among other examples.

Forming the reconstituted portion 270 may include forming interface region 275 between the reconstituted portion 270 and a portion of a native semiconductive material (e.g., the portion 260-1 of the semiconductive material used to form the elongated structures as described in connection with FIG. 4A). A deposition operation used to form the interface region 275 (e.g., an epitaxial growth operation) may leave traces of elements such as fluorine, chlorine, or nitrogen in the interface regions, where the traces of elements are detectable using an atom probe tomography (ATM) analysis or a transmission electron microscopy (TEM) analysis. In some implementations, the traces of elements may have sizes on the order of tens to hundreds of nanometers.

As shown in FIG. 4E, the dielectric structures 235 are formed on and/or along surfaces (e.g., sidewall surfaces) of the reconstituted portion 270. Forming the dielectric structures 235 (e.g., one or more dielectric layers) may include depositing (e.g., depositing or growing) an insulative material over, on, and/or around surfaces of the reconstituted portion 270. The insulative material used to form the dielectric structures 235 may comprise, consist of, or consist essentially of nitride (e.g., silicon nitride or aluminum nitride). Alternatively, the insulative material used to form the dielectric structures 235 may comprise, consist, or consist essentially of oxide (e.g., silicon dioxide or aluminum oxide) or another suitable insulative material, among other examples. In some implementations, the insulative material used to form the reconstituted portions is planarized by a chemical/mechanical planarization (CMP) technique after deposition.

In some implementations, and as further shown in FIG. 4E, the dielectric structures 240 are formed over and/or on surfaces (e.g., top surfaces) of at least one portion of the elongated active areas 205 (e.g., the portion 260-2), the dielectric structures 235, and the reconstituted portion 270. Forming the dielectric structures 240 (e.g., one or more dielectric layers) may include depositing (e.g., depositing or growing) an insulative material over and/or on surfaces of the elongated active areas 205, the dielectric structures 235, and the reconstituted portion 270. The insulative material used to form the dielectric structures 240 may comprise, consist of, or consist essentially of nitride (e.g., silicon nitride or aluminum nitride). Alternatively, the insulative material used to form the dielectric structures 240 may comprise, consist, or consist essentially of oxide (e.g., silicon dioxide or aluminum oxide) or another suitable insulative material, among other examples. In some implementations, the insulative material used to form the reconstituted portions is planarized by a chemical/mechanical planarization (CMP) technique or another suitable planarization technique after deposition.

As indicated above, the process steps described in connection with FIGS. 4A through 4E are provided as examples. Other examples may differ from what is described with respect to FIGS. 4A through 4E. The structure shown in FIG. 4E may be equivalent to the memory device structure 200 described elsewhere herein. In process steps above that describe forming material, such material may be formed, for example, using chemical vapor deposition, epitaxial deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

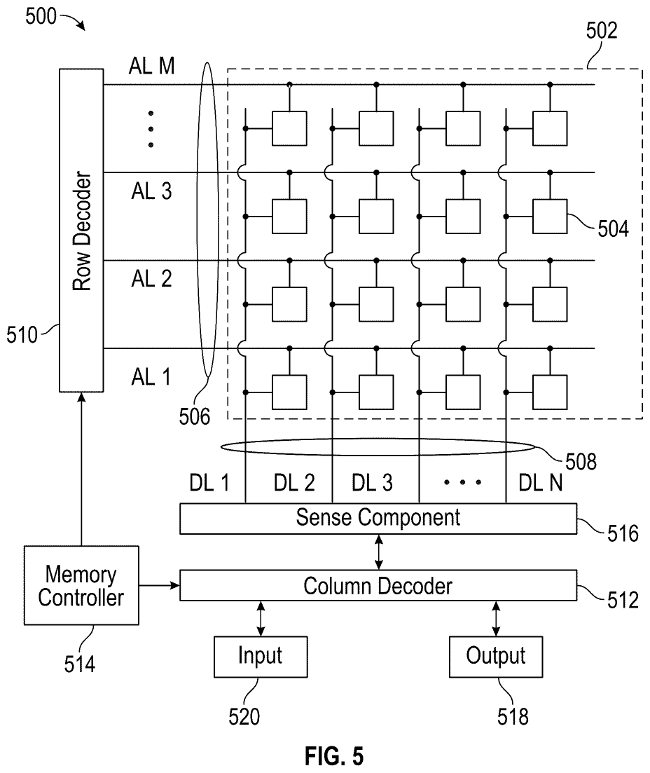

FIG. 5 is a diagrammatic view of an example memory device 500. The memory device 500 may include a memory array 502 that includes multiple memory cells 504. A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (shown as access lines AL 1 through AL M) and digit line 508 (shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1. Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

In some implementations, the memory device 500 includes one or more active areas including portions of epitaxial regrowth (e.g., the elongated active areas 205 including the reconstituted portion 270) and/or an integrated assembly that includes one or more active areas including epitaxial regrowth. For example, the memory array 502 may include one or more active areas including portions of epitaxial regrowth and/or an integrated assembly that includes one or more active areas including portions of epitaxial regrowth. Additionally, or alternatively, the memory cell 504 may include a memory cell described elsewhere herein.

As indicated above, FIG. 5 is provided as an example. Other examples may differ from what is described with respect to FIG. 5.

In some implementations, an integrated assembly includes an elemental region having a first width, comprising: a first native portion of a semiconductive material; and a composite region over the elemental region and having a second width that is greater than or equal to the first width, the composite region comprising: a second native portion of the semiconductive material that is directly conjoined with the first native portion, and a reconstituted portion of the semiconductive material that is directly conjoined with the second native portion and that extends away from the second native portion.

In some implementations, an apparatus includes a semiconductor structure, comprising: an active area disposed along a vertical axis, comprising: a lower segment, comprising: a first portion of a first semiconductive material, wherein the first portion has first width; and an upper segment, comprising: a second portion of the first semiconductive material that is on the first portion, wherein the second portion has a second width that is less than or equal to the first width; and a regrowth portion of a second semiconductive material that is conjoined with the second portion of the first semiconductive material along an interface region, wherein the regrowth portion extends laterally away from the vertical axis, and wherein the interface region comprises traces of impurities.

In some implementations, a method includes forming an elongated active area from a semiconductive material; forming a dielectric layer on a surface of the elongated active area; recessing the recessing the dielectric layer to expose a tip region of the elongated active area and remove a first amount of the semiconductive material; and forming a second amount of the semiconductive material that replaces the first amount.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
an elemental region having a first width, comprising:
a first native portion of a semiconductive material; and
a composite region over the elemental region and having a second width that is greater than or equal to the first width, the composite region comprising:
a second native portion of the semiconductive material that is directly conjoined with the first native portion, and
a reconstituted portion of the semiconductive material that is directly conjoined with the second native portion and extends away from the second native portion.

2. The integrated assembly of claim 1, wherein the reconstituted portion overlaps a dielectric structure that is proximate to the elemental region.

3. The integrated assembly of claim 1, wherein the reconstituted portion overlaps the first native portion.

4. The integrated assembly of claim 1, further comprising:
a dielectric structure that is over the composite region and directly on surfaces of the second native portion and the reconstituted portion.

5. The integrated assembly of claim 1, wherein the elemental region includes an oxidized sidewall that extends from a base of the elemental region to a base of the composite region.

6. The integrated assembly of claim 5, wherein the reconstituted portion overlaps the oxidized sidewall.

7. The integrated assembly of claim 1, further comprising:
at least one dielectric structure that is directly on and along a sidewall of the reconstituted portion.

8. An apparatus, comprising:
a semiconductor structure, comprising:
an active area disposed along a vertical axis, comprising:
a lower segment, comprising:
a first portion of a first semiconductive material,
wherein the first portion has first width; and
an upper segment, comprising:
a second portion of the first semiconductive material that is on the first portion,
wherein the second portion has a second width that is less than or equal to the first width; and
a regrowth portion of a second semiconductive material that is conjoined with the second portion of the first semiconductive material along an interface region,
wherein the regrowth portion extends laterally away from the vertical axis, and
wherein the interface region comprises traces of impurities.

9. The apparatus of claim 8, wherein the first semiconductive material and the second semiconductive material are a same semiconductive material.

10. The apparatus of claim 8, wherein the first semiconductive material and the second semiconductive material are different semiconductive materials.

11. The apparatus of claim 8, wherein the active area is a contact structure of a memory device,
wherein the contact structure is part of an electrical connection between a transistor and a digit line, or
wherein the contact structure is part of an electrical connection between the transistor and a capacitor.

12. The apparatus of claim 8, wherein the traces of impurities comprise one or more of:
chlorine,
fluorine, or
nitrogen.

13. A method, comprising:
forming an elongated active area from a semiconductive material;
forming a dielectric structure on a surface of the elongated active area;
recessing the dielectric structure to expose a tip region of the elongated active area and remove a first amount of the semiconductive material; and
forming a second amount of the semiconductive material that replaces the first amount.

14. The method of claim 13, wherein the second amount is greater than the first amount.

15. The method of claim 13, wherein forming the second amount includes:
forming the second amount using an epitaxial regrowth operation.

16. The method of claim 15, wherein forming the second amount using the epitaxial regrowth operation includes:
selectively forming the second amount directly on an exposed surface of the elongated active area in the tip region.

17. The method of claim 13, wherein forming the second amount includes:
forming an interface region.

18. The method of claim 17, wherein forming the interface region includes:
forming traces of chlorine in the interface region,
forming traces of fluorine in the interface region, or
forming traces of nitrogen in the interface region.

19. The method of claim 13, further comprising:
forming a dielectric structure along a sidewall of the second amount.

20. The method of claim 19, wherein the dielectric structure is a first dielectric structure, and further comprising:
forming a second dielectric structure directly on an exposed surface of the first dielectric structure and an exposed surface of the elongated active area that includes an exposed surface of the second amount.
